(19) United States
(12) Patent Application Publication
(10) Pub. No.: US 2026/0173605 A1
(43) Pub. Date: Jun. 18, 2026

(54) DISPLAY DEVICE AND REPAID METHOD THEREOF

(71) Applicant: AUO Corporation, Hsinchu City (TW)

(72) Inventors: Fu-Wei Chan, Hsinchu City (TW); Kuan-Hsun Chen, Hsinchu City (TW)

(73) Assignee: AUO Corporation, Hsinchu City (TW)

(21) Appl. No.: 19/266,198

(22) Filed: Jul. 11, 2025

(30) Foreign Application Priority Data
Dec. 13, 2024 (TW) 113148706

(51) Int. Cl. H10H 29/01; H10H 29/853

(52) U.S. Cl. CPC H10H 29/0362; H10H 29/853

(57) ABSTRACT

A display device includes a panel, a packaging layer, a plurality of light emitting elements, an optical film, and at least one adhesive. The packaging layer is disposed on a surface of the panel. The plurality of light emitting elements is arranged in the packaging layer. The optical film covers the packaging layer and includes an open zone. The at least one adhesive is filled in the open zone. A repair method of the display device is also provided.

### CROSS-REFERENCE TO RELATED APPLICATION

This application claims the priority benefit of Taiwan application serial no. 113148706, filed on December 13, 2024. The entirety of the above-mentioned patent application is hereby incorporated by reference herein and made a part of this specification.

### BACKGROUND

### TECHNICAL FIELD

The disclosure relates to a display device and a repair method thereof, and in particular to a display device having an optical film and a repair method thereof.

### DESCRIPTION OF RELATED ART

Generally, a display device such as a micro-LED display may cover an optical film on the panel to protect the panel and provide specific optical effects such as a reduction in reflectivity. However, during the process of covering the optical film on the panel, if foreign objects accidentally enter between the optical film and the surface of the panel, bubbles may form around which the foreign objects are located after completion. This may not only render the display device unattractive but also compromise the quality of display.

### SUMMARY

The disclosure provides a display device and a repair method thereof, which may eliminate bubbles between the optical film and the panel.

A display device of the disclosure includes a panel, a packaging layer, a plurality of light emitting elements, an optical film, and at least one adhesive. The packaging layer is disposed on a surface of the panel. The plurality of light emitting elements is arranged in the packaging layer. The optical film covers the packaging layer and includes an open zone. The at least one adhesive is filled in the open zone.

In an embodiment of the disclosure, the packaging layer includes at least one circuit area, and the open zone is not overlapped with the at least one circuit area in a direction vertical to the surface.

In an embodiment of the disclosure, a distance between a central axis of the open zone and the at least one circuit area is greater than 150 μm.

In an embodiment of the disclosure, the open zone has a top surface and a bottom surface opposite to each other. The bottom surface is located between the top surface and the panel, and a ratio of a width of the bottom surface to a width of the top surface is between 0.09 and 1.

In an embodiment of the disclosure, when a spacing between two adjacent light-emitting elements of the plurality of the light-emitting elements is greater than 500 μm, the ratio is between 0.4 and 1.

In an embodiment of the disclosure, when a spacing between two adjacent light-emitting elements of the plurality of light-emitting elements is less than 500 μm, the ratio is between 0.09 and 0.4.

In an embodiment of the disclosure, a width of the bottom surface is between 20 μm and 500 μm.

In an embodiment of the disclosure, a spacing between a highest point of an outer surface of the at least one adhesive and an outer surface of the optical film is less than or equal to 10 μm.

In an embodiment of the disclosure, the packaging layer is transparent, a position of a top end of the packaging layer is higher than a position of a top end of each of the plurality of light-emitting elements.

In an embodiment of the disclosure, the display device further includes an adhesive layer. The adhesive layer is disposed between the optical film and the packaging layer, and the open zone penetrates the optical film and the adhesive layer.

In an embodiment of the disclosure, a difference between a reflectivity of the at least one adhesive in the open zone and a reflectivity of the optical film is less than or equal to 0.3.

In an embodiment of the disclosure, the at least one adhesive includes a first adhesive and a second adhesive. The first adhesive is filled in a first portion of the open zone, and the second adhesive is filled in a second portion of the open zone. The first portion is located between the panel and the second portion, and the first adhesive is different from the second adhesive.

In an embodiment of the disclosure, an optical density of the at least one adhesive is greater than 3.

In an embodiment of the disclosure, the packaging layer includes a transparent adhesive, and the optical film contains scattering particles.

A repair method of a display device in the disclosure includes the following steps. A display device, including a panel, a packaging layer, a plurality of light-emitting elements and an optical film, is provided. The packaging layer is disposed on the surface of the panel, the plurality of light-emitting elements is arranged in the packaging layer, and the optical film covers the packaging layer. An open zone in the optical film is formed by irradiating a part of the optical film with a laser beam. The open zone corresponds to a bubble, and the bubble exists between the optical film and the packaging layer. A pressurization and heating procedure is performed on the display device so as to remove the bubble. At least one adhesive is filled in the open zone.

In summary, in the display device and its repair method of the disclosure, if a bubble exists between the optical film and the packaging layer after the optical film covers the packaging layer on the panel, an open zone may be formed by irradiating a part of the optical film corresponding to the bubble with a laser beam, and a pressurization and heating procedure may be performed on the display device, so that the gas in the bubble is discharged to the outside of the device through the open zone, thereby eliminating the bubble without any rework on the optical film. After eliminating the bubble in the display device, an adhesive may be further filled in the open zone to fill the opening and enhance device aesthetics.

### BRIEF DESCRIPTION OF THE DRAWINGS

FIG. 1 is a side view of a display device according to an embodiment of the disclosure.

FIG. 2 is an enlarged partial view of the display device of FIG. 1.

FIG. 3 is a side view of a display device according to another embodiment of the disclosure.

FIG. 4 is a side view of a display device according to another embodiment of the disclosure.

FIG. 5 is a flow diagram of a repair method for a display device according to an embodiment of the disclosure.

FIG. 6A to FIG. 6D illustrate a process flow of a repair method for a display device according to an embodiment of the disclosure.

FIG. 7A is a schematic view of the irradiation of a laser beam according to an embodiment of the disclosure.

FIG. 7B is a schematic view of the irradiation of a laser beam according to another embodiment of the disclosure.

### DESCRIPTION OF THE EMBODIMENTS

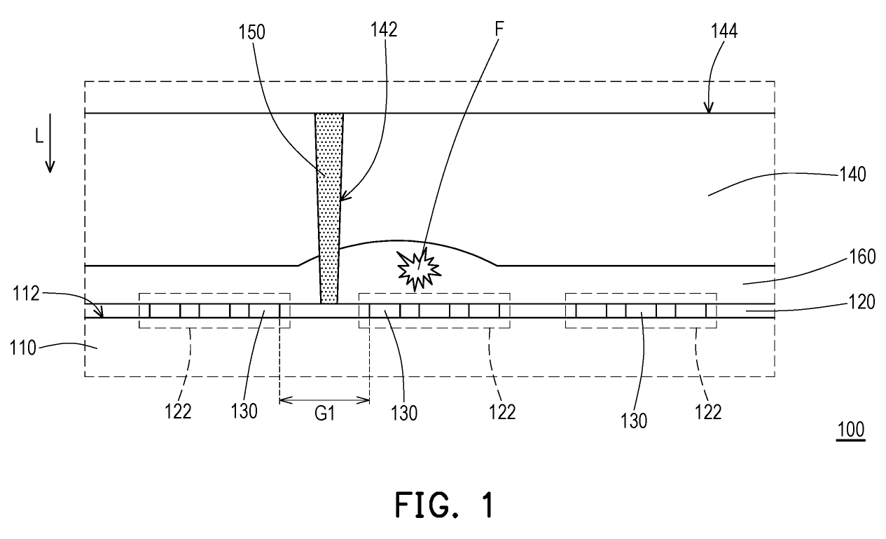

FIG. 1 is a side view of a display device according to an embodiment of the disclosure. To clearly present the adhesive, the adhesive in FIG. 1 is drawn as dots. Additionally, the circuit area is schematically drawn with dotted lines in FIG. 1.

Referring to FIG. 1, the display device 100 in this embodiment is, for example, a television, but the type of the display device 100 is not limited thereto. The display device 100 includes a panel 110, a packaging layer 120, a plurality of light-emitting elements 130, an optical film 140, and at least one adhesive 150. The packaging layer 120 is disposed on a surface 112 of the panel 110. The plurality of light-emitting elements 130 is arranged in the packaging layer 120. The optical film 140 covers the packaging layer 120 and includes an open zone 142, and the at least one adhesive 150 fills the open zone 142.

Generally, during the process of covering the optical film 140 on the panel 110, if a foreign object F accidentally enters between the optical film 140 and the packaging layer 120, a bubble may form around the foreign object F (this will be further introduced later). The bubble may not only render the display device 100 unattractive but also compromise the display quality of the display device 100.

In this embodiment, the gas in the aforementioned bubble may be discharged to the outside of the display device 100 through the open zone 142, thereby eliminating the bubble without any rework on the optical film 140. After eliminating the bubble between the optical film 140 and the packaging layer 120, the adhesive 150 fills the open zone 142, which not only fills the opening but also enhances device aesthetics. The technical features of the embodiments of the disclosure will be further illustrated below.

The plurality of light-emitting elements 130 in this embodiment is, for example, micro light emitting diodes (micro-LED) whose light beams may form a display image. The packaging layer 120 is black and includes at least one circuit area 122 (FIG. 1 schematically illustrates three circuit areas 122). Each of the circuit areas 122 may include circuits and light-emitting elements 130.

The optical film 140 in this embodiment may protect the panel 110 and provide specific optical effects such as a reduction in reflectivity and scattering, but the optical effects provided by the optical film 140 are not limited thereto.

The display device 100 further includes an adhesive layer 160. The adhesive layer 160 is disposed between the optical film 140 and the packaging layer 120 to bond the optical film 140 to the packaging layer 120 of the panel 110. The adhesive layer 160 is, for example, an optically clear adhesive (OCA) or a pressure sensitive adhesive (PSA), but the type of the adhesive layer 160 is not limited thereto. The total thickness of the optical film 140 and the adhesive layer 160 is between 100 μm and 300 μm, for example.

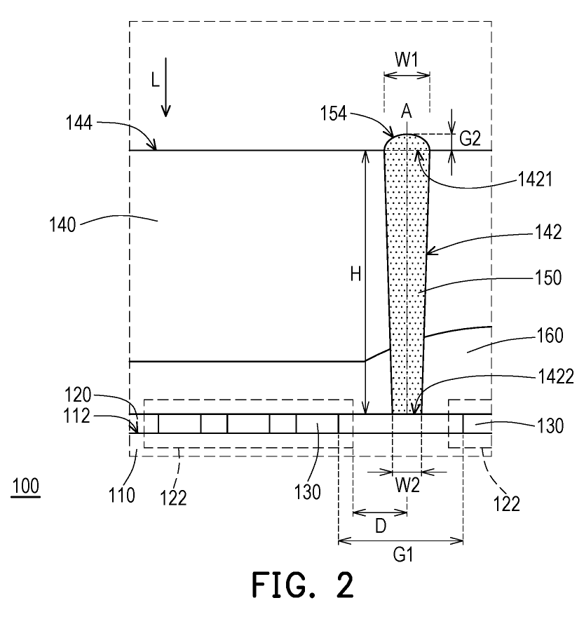

FIG. 2 is an enlarged partial view of the display device of FIG. 1. Referring to FIG. 2, the open zone 142 in this embodiment is a space that penetrates the optical film 140 and the adhesive layer 160. That is, the depth H of the open zone 142 is greater than or equal to the sum of the height of the optical film 140 and the height of the adhesive layer 160. The open zone 142 is a space not overlapped with the circuit areas 122 in a direction L perpendicular to the surface 112 of the panel 110.

Preferably, the open zone 142 is formed only in the optical film 140 and the adhesive layer 160. During the process of forming the open zone 142, even if the open zone 142 extends to the packaging layer 120 below the adhesive layer 160 due to a cut error, damage to the light-emitting elements 130 and circuits in the circuit areas 122 may be avoided since the open zone 142 is not overlapped with the circuit areas 122 in the direction L perpendicular to the surface 112. Furthermore, the distance D between the central axis A of the open zone 142 and the circuit area 122 is greater than 150 μm, further preventing the cut range of the open zone 142 from affecting the circuit area 122.

The open zone 142 has a top surface 1421 and a bottom surface 1422 opposite to each other. The bottom surface 1422 is located between the top surface 1421 and the panel 110. The width W2 of the bottom surface 1422 is between 20 μm and 500 μm, thereby preventing the open zone 142 from disappearance due to meltback of the optical film 140 and the adhesive layer 160 when an opening is too small.

The ratio of the width W2 of the bottom surface 1422 to the width W1 of the top surface 1421 is between 0.09 and 1. When the spacing G1 between two adjacent ones of the light-emitting elements 130 is greater than 500 μm, the aforementioned ratio is between 0.4 and 1. When the spacing G1 between two adjacent ones of the light-emitting elements 130 is less than 500 μm, the aforementioned ratio is between 0.09 and 0.4.

In this way, an open zone 142 with appropriate dimensions may be formed so as to allow the gas in the aforementioned bubble to be discharged to the outside of the display device 100 through the open zone 142, thereby achieving the removal of the bubble and avoiding affecting the light-emitting elements 130 and circuits in the circuit area 122 when making the open zone 142.

The adhesive 150 in this embodiment fills the open zone 142. The viscosity of the adhesive 150 is between 1 cps and 800 cps to ensure flatness of the adhesive 150. The spacing G2 between the highest point of an outer surface 154 of the adhesive 150 and an outer surface 144 of the optical film 140 is less than or equal to 10 μm.

In this embodiment, the outer surface 154 of the adhesive 150 is higher than the outer surface 144 of the optical film 140. In another embodiment, the outer surface 154 of the adhesive 150 is lower than the outer surface 144 of the optical film 140. In one more embodiment, the outer surface 154 of the adhesive 150 is flush with the outer surface 144 of the optical film 140.

Moreover, the difference between the reflectivity of the adhesive 150 and the reflectivity of the optical film 140 is less than or equal to 0.3, so as to reduce the visual difference between the repaired area and the non-repaired area, thereby achieving excellent display quality. Additionally, the optical density of the adhesive 150 in this embodiment is greater than 3, so as to reduce light transmittance.

In this embodiment, the open zone 142 is formed in the optical film 140 and the adhesive layer 160, and a transparent adhesive may be employed as the adhesive 150 to fill the open zone 142 to enhance aesthetic appearance. While a transparent adhesive is applied as the adhesive 150, it may further cooperate with an optical film 140 containing scattering particles, such as an ART-type optical film to enhance the overall optical effect.

In another embodiment, the open zone 142 extends into the packaging layer 120 below the adhesive layer 160 due to a cut error, for example. That is, a portion of the black packaging layer 120 is removed. In such scenario, a black adhesive may be employed as the adhesive 150 to fill the open zone 142 to achieve black masking.

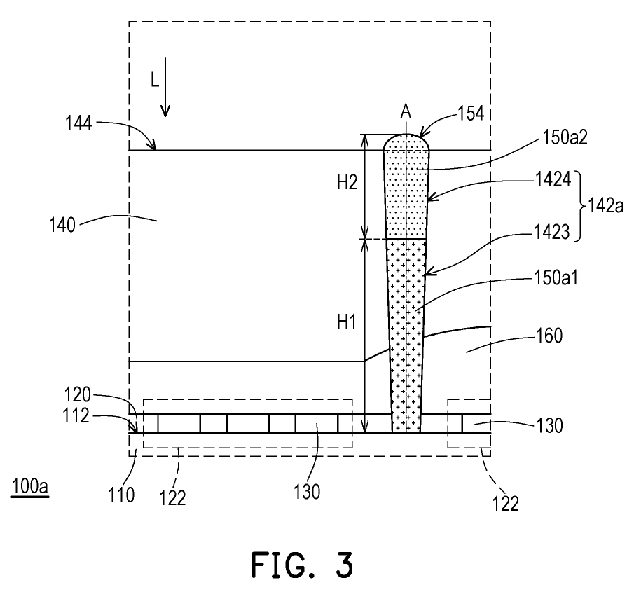

FIG. 3 is a side view of a display device according to another embodiment of the disclosure. A main difference between the embodiment illustrated in FIG. 3 and the embodiment illustrated in FIG. 2 is that the open zone 142 of the display device 100a is filled with two types of adhesives in FIG. 3.

Specifically, the adhesives in this embodiment include a first adhesive 150a1 and a second adhesive 150a2. The first adhesive 150a1 fills a first portion 1423 of the open zone 142a, the second adhesive 150a2 fills a second portion 1424 of the open zone 142a, and the first portion 1423 is located between the panel 110 and the second portion 1424. The first adhesive 150a1 is different from the second adhesive 150a2. For example, the first adhesive 150a1 is a black adhesive, and the second adhesive 150a2 is a transparent adhesive.

In this embodiment, the open zone 142a extends into the packaging layer 120 below the adhesive layer 160 due to a cut error. That is, a portion of the black packaging layer 120 is removed. In such scenario, the first portion 1423 of the open zone 142a may be filled with the first adhesive 150a1 (i.e., the black adhesive) to achieve black masking, and then the second portion 1424 of the open zone 142a may be filled with the second adhesive 150a2 (i.e., the transparent adhesive) to enhance device appearance.

Furthermore, the depth H1 of the first adhesive 150a1 and the depth H2 of the second adhesive 150a2 may be determined based on the amount of the first adhesive 150a1. If the first adhesive 150a1 is a black adhesive, when the thickness of the first adhesive 150a1 increases, the optical density of the first adhesive 150a1 will increase accordingly. After the optical density of the first adhesive 150a1 reaches the required value, the remaining portion of the open zone 142a may be filled with the second adhesive 150a2, for example, a transparent adhesive.

The remaining components and configuration of the display device 100a in this embodiment are identical or similar to those of the display device 100 in the aforementioned embodiment and will not be reiterated here.

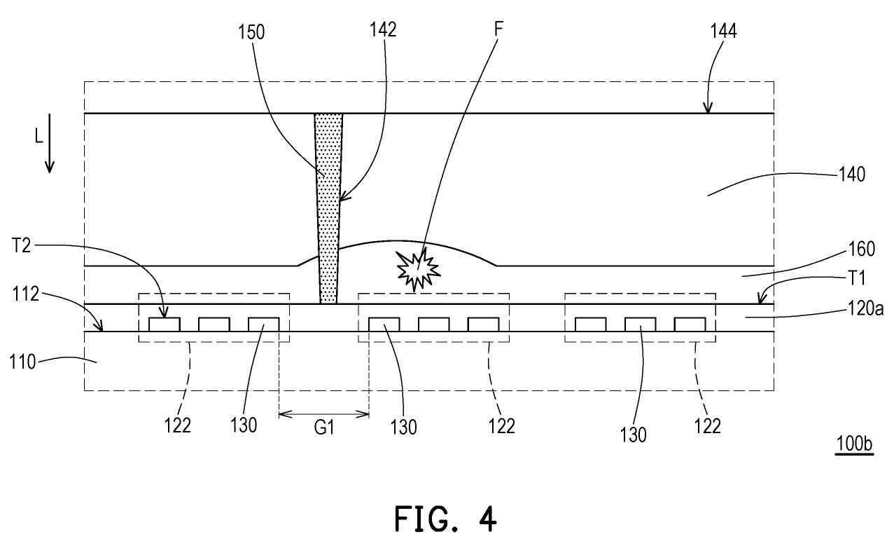

FIG. 4 is a side view of a display device according to another embodiment of the disclosure. A main difference between the embodiment illustrated in FIG. 4 and the embodiment illustrated in FIG. 1 is that the packaging layer 120a of the display device 100b is transparent in FIG. 3. In this embodiment, the position of the top end T1 of the packaging layer 120a is higher than the position of the top end T2 of the light-emitting element 130. Because the packaging layer 120a is transparent, the adhesive 150 filling the open zone 142 may be a transparent adhesive, and thus there is no need to use a black adhesive for black masking.

The remaining components and configuration of the display device 100b in this embodiment are identical or similar to those of the display device 100 in the aforementioned embodiment and will not be reiterated here.

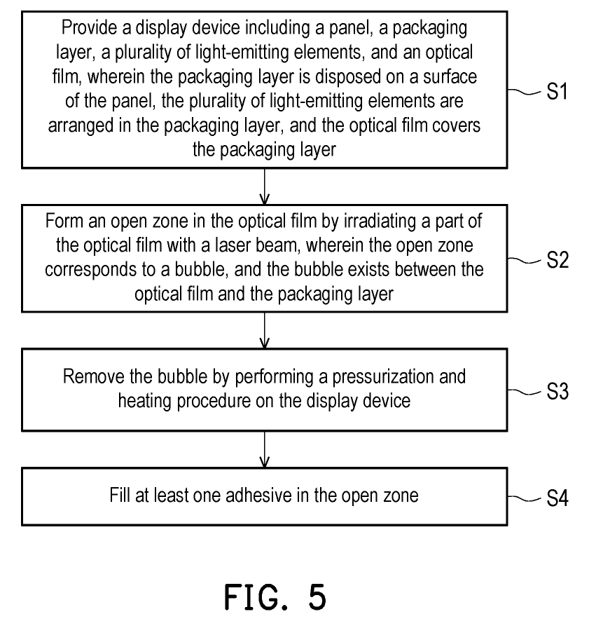

Presented below is a repair method for the display device 100 in an embodiment of the disclosure. FIG. 5 is a flow diagram of a repair method for a display device according to an embodiment of the disclosure. Referring to FIG. 5 and FIG. 1, first, a display device 100, including a panel 110, a packaging layer 120, a plurality of light-emitting elements 130, and an optical film 140, is provided, wherein the packaging layer 120 is disposed on the surface 112 of the panel 110, the light-emitting elements 130 are arranged in the packaging layer 120, and the optical film 140 covers the packaging layer 120 (step S1).

Next, an open zone 142 is formed in the optical film 140 by irradiating a part of the optical film 140 with a laser beam, wherein the open zone 142 corresponds to a bubble, and the bubble exists between the optical film 140 and the packaging layer 120 (step S2). Next, a pressurization and heating procedure is performed on the display device 100 to remove the bubble (step S3). Afterwards, at least one adhesive 150 is filled in the open zone 142 (step S4).

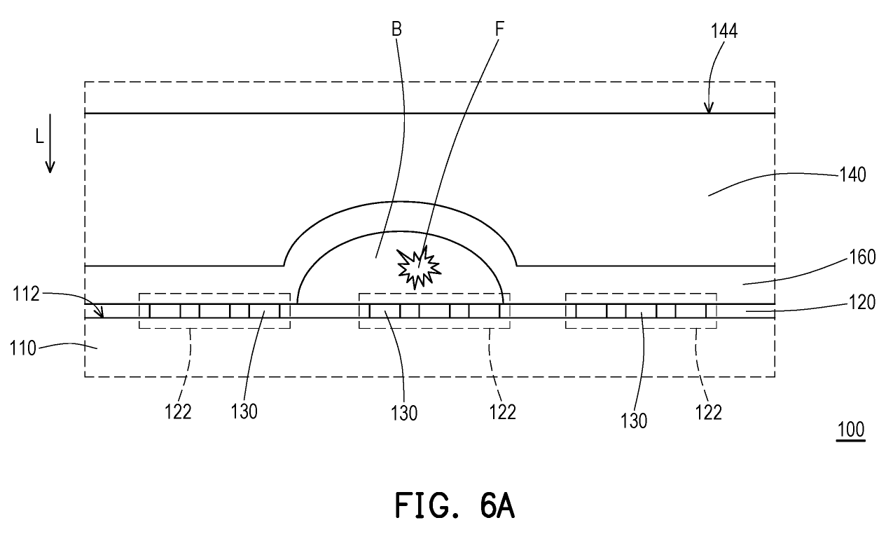

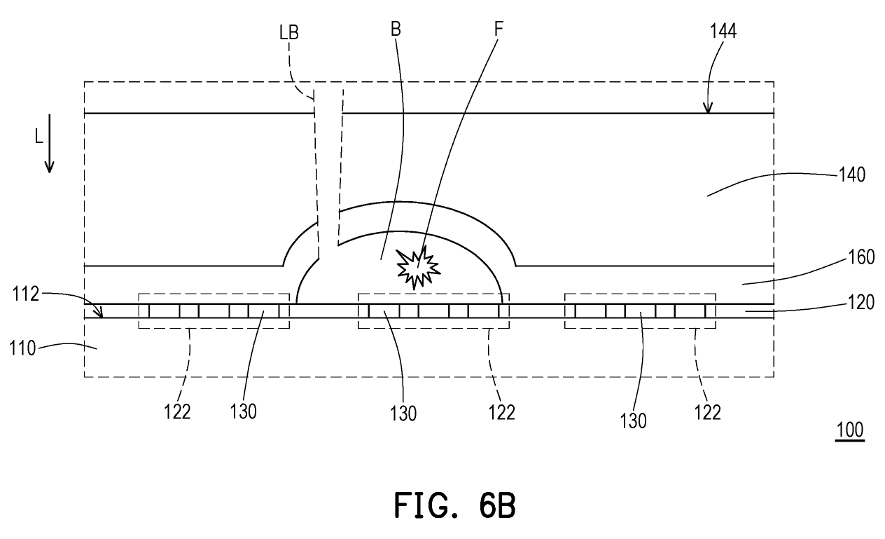

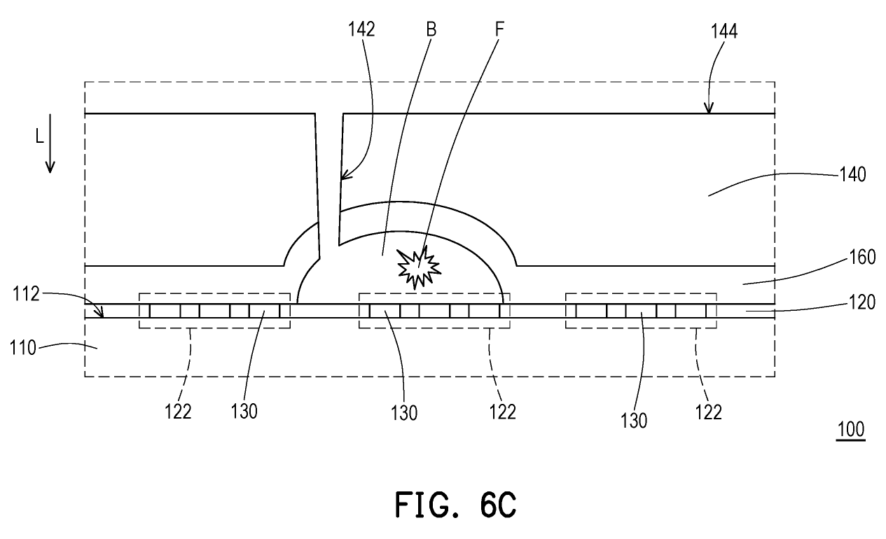

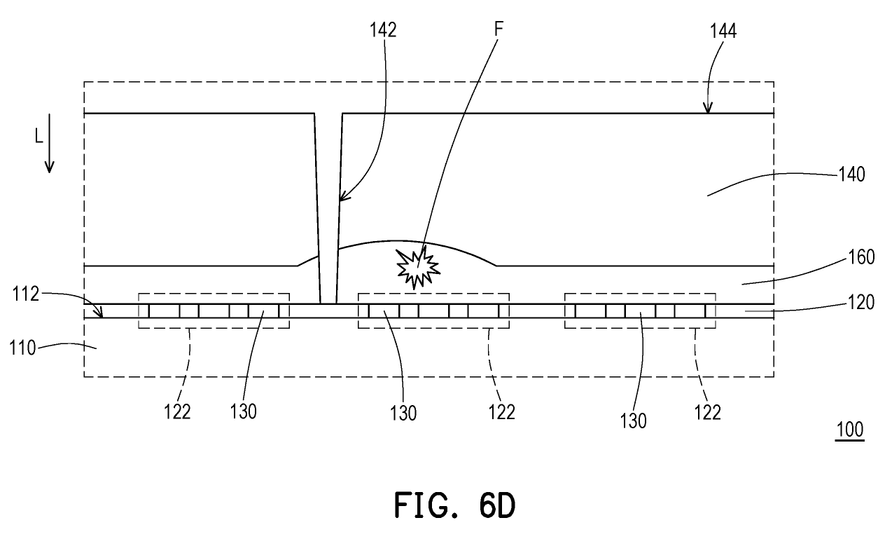

The specific repair process for the display device 100 will be illustrated in more detail below. FIG. 6A to FIG. 6D illustrate a process flow of a repair method for a display device according to an embodiment of the disclosure. The laser beam is drawn with dotted lines in FIG. 6B.

First, as illustrated in FIG. 6A, the display device 100 includes a panel 110, a packaging layer 120, a plurality of light-emitting elements 130, an optical film 140, and an adhesive layer 160. In the process of covering the optical film 140 onto the panel 110, a foreign object F exists between the optical film 140 and the packaging layer 120 of the panel 110. More specifically, the foreign object F is located between the adhesive layer 160 and the packaging layer 120, and a bubble B may form around the foreign object F. The existence of the bubble B may not only render the display device 100 unattractive but also reduce the display quality of the display device 100.

To eliminate the bubble B, as illustrated in FIG. 6B and FIG. 6C, a part of the optical film 140, that is, the part corresponding to the bubble B, is irradiated with a laser beam LB to form an open zone 142 in the optical film 140 and the adhesive layer 160 thereunder. The optical film 140 and adhesive layer 160 within the open zone 142 irradiated by the laser beam LB will be melted and eliminated by the laser beam LB.

Preferably, the laser beam LB is controlled to strike the optical film 140 and the adhesive layer 160, so as to form the open zone 142 only in the optical film 140 and the adhesive layer 160. In some embodiments, the laser beam LB may, due to a control error, strike the packaging layer 120 below the adhesive layer 160 and remove at least a portion of the packaging layer 120. However, since the area irradiated by the laser beam LB (that is, the open zone 142) is not overlapped with the circuit areas 122 in the direction L perpendicular to the surface 112, the light-emitting elements 130 and circuits in the circuit areas 122 are not damaged.

Next, as illustrated in FIG. 6D, a pressurization and heating procedure is performed on the display device 100; for example, the display device 100 is placed into a pressurized bubble remover. Under high temperature and high pressure, the gas inside the bubble B may escape from the open zone 142. After removing the gas inside the bubble B, the optical film 140 and adhesive layer 160 above the bubble B collapse downward and adhere to the surface 112 of the packaging layer 120. In this way, the bubble B is removed from the display device 100.

Next, returning to FIG. 1, after the bubble B is completely eliminated, the adhesive 150 may fill the open zone 142, so as to fill the opening and enhance aesthetic appearance. The adhesive 150 may include at least one of a transparent adhesive and a black adhesive and may fill the open zone 142 according to various requirements as described above.

For example, when the open zone 142 exists only in the optical film 140 and the adhesive layer 160, a transparent adhesive may be employed as the adhesive 150 to enhance aesthetic appearance. When the open zone 142 extends into the packaging layer 120 due to a cut error, a black adhesive may be employed as the adhesive 150 to achieve black masking, or a black adhesive and a transparent adhesive may be applied sequentially to achieve both black masking and aesthetic purposes. At this point, the repair process for the display device 100 is completed.

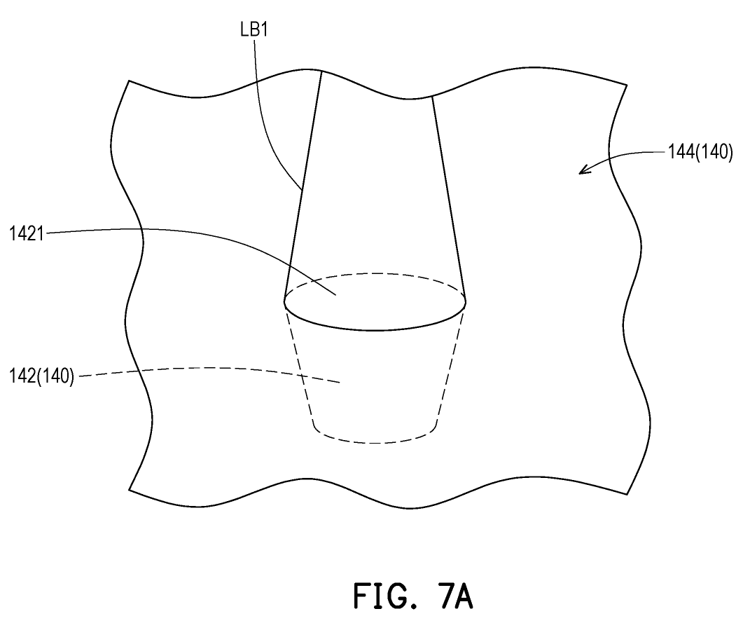

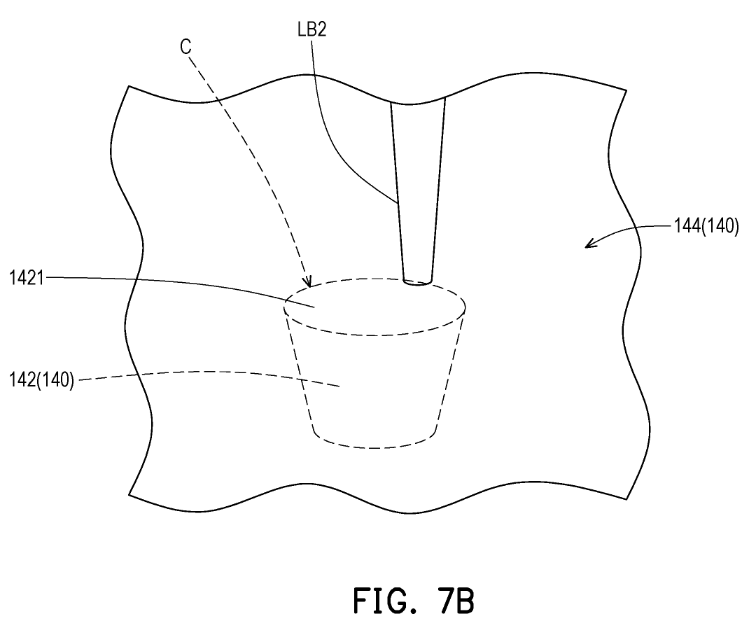

FIG. 7A is a schematic view of the irradiation of a laser beam according to an embodiment of the disclosure. FIG. 7B is a schematic view of the irradiation of a laser beam according to another embodiment of the disclosure. In the step in FIG. 6B, the irradiation of the laser beam may include two types as follows, for example.

In the embodiment illustrated in FIG. 7A, the laser beam LB1 has a larger diameter and is fixedly directed to a specific area on the outer surface 144 of the optical film 140, which may cut and form the open zone 142, where the irradiation area of the laser beam LB1 is the area of the top surface 1421 of the open zone 142. This laser cutting method may be referred to as “surface cutting.” Surface cutting is suitable for the scenario where the spacing G1 (FIG. 2) between the light-emitting elements 130 is greater than 500 μm, so as to avoid the cutting range of surface cutting being so large that the light-emitting elements 130 in the circuit area 122 are damaged.

The energy of the laser beam LB1 for surface cutting may be 20 W, for example, the width W2 (FIG. 2) of the bottom surface 1422 of the formed open zone 142 may be 310 μm, the width W1 (FIG. 2) of the top surface 1421 of the open zone 142 may be 338 μm, and the ratio of the width W2 of the bottom surface 1422 to the width W1 of the top surface 1421 is approximately 0.9.

In the embodiment illustrated in FIG. 7B, the laser beam LB2 has a smaller diameter. The laser beam LB2 may, for example, move along the periphery C of the top surface 1421 of the open zone 142 to perform continuous cutting, and meanwhile the optical film 140 within the periphery C is also cut out. After the laser beam LB2 completes traveling along the periphery C, the open zone 142 may be formed. This laser cutting method may be referred to as “line cutting.” Line cutting has a smaller cutting range, so it may be suitable for the scenario where the spacing G1 between the light-emitting elements 130 is less than 500 μm, so as to perform precisely focused cutting and avoid damaging the light-emitting elements 130.

The energy of the laser beam LB2 for line cutting may be 30 W, for example, the width W2 of the bottom surface 1422 of the formed open zone 142 may be 30 μm, the width W1 (FIG. 2) of the top surface 1421 of the open zone 142 may be 139 μm, and the ratio of the width W2 of the bottom surface 1422 to the width W1 of the top surface 1421 is approximately 0.2.

It should also be noted that FIG. 1 to FIG. 4 and FIG. 6A to FIG. 6D of the disclosure schematically illustrate the components of the display devices 100, 100a, 100b, the open zones 142, 142a, and the bubble B, but they are not intended to limit the thickness of these components, the size and position of the open zones 142, 142a, and the range and position of the bubble B.

In summary, in the display device and its repair method of the disclosure, if a bubble exists between the optical film and the packaging layer after the optical film covers the packaging layer on the panel, an open zone may be formed by irradiating a part of the optical film corresponding to the bubble with a laser beam, and a pressurization and heating procedure may be performed on the display device, so that the gas in the bubble is discharged to the outside of the device through the open zone, thereby eliminating the bubble without any rework on the optical film. After eliminating the bubble in the display device, an adhesive may be further filled in the open zone to fill the opening and enhance device aesthetics.

What is claimed is:

1. A display device, comprising:
a panel;
a packaging layer, disposed on a surface of the panel;
a plurality of light-emitting elements, arranged in the packaging layer;
an optical film, covering the packaging layer and comprising an open zone; and
at least one adhesive, filled in the open zone.

2. The display device according to claim 1, wherein the packaging layer comprises at least one circuit area, and the open zone is not overlapped with the at least one circuit area in a direction vertical to the surface.

3. The display device according to claim 2, wherein a distance between a central axis of the open zone and the at least one circuit area is greater than 150 μm.

4. The display device according to claim 1, wherein the open zone has a top surface and a bottom surface opposite to each other, the bottom surface is located between the top surface and the panel, and a ratio of a width of the bottom surface to a width of the top surface is between 0.09 and 1.

5. The display device according to claim 4, wherein when a spacing between two adjacent light-emitting elements of the plurality of the light-emitting elements is greater than 500 μm, the ratio is between 0.4 and 1.

6. The display device according to claim 4, wherein when a spacing between two adjacent light-emitting elements of the plurality of light-emitting elements is less than 500 μm, the ratio is between 0.09 and 0.4.

7. The display device according to claim 1, wherein the open zone has a top surface and a bottom surface opposite to each other, the bottom surface is located between the top surface and the panel, and a width of the bottom surface is between 20 μm and 500 μm.

8. The display device according to claim 1, wherein a spacing between a highest point of an outer surface of the at least one adhesive and an outer surface of the optical film is less than or equal to 10 μm.

9. The display device according to claim 1, wherein the packaging layer is transparent, a position of a top end of the packaging layer is higher than a position of a top end of each of the plurality of light-emitting elements.

10. The display device according to claim 1, further comprising an adhesive layer, wherein the adhesive layer is disposed between the optical film and the packaging layer, and the open zone penetrates the optical film and the adhesive layer.

11. The display device according to claim 1, wherein a difference between a reflectivity of the at least one adhesive in the open zone and a reflectivity of the optical film is less than or equal to 0.3.

12. The display device according to claim 1, wherein the at least one adhesive comprises a first adhesive and a second adhesive, the first adhesive is filled in a first portion of the open zone, the second adhesive is filled in a second portion of the open zone, the first portion is located between the panel and the second portion, and the first adhesive is different from the second adhesive.

13. The display device according to claim 1, wherein an optical density of the at least one adhesive is greater than 3.

14. The display device according to claim 1, wherein the at least one adhesive comprises a transparent adhesive, and the optical film contains scattering particles.

15. A repair method of a display device, comprising:
providing a display device comprising a panel, a packaging layer, a plurality of light-emitting elements, and an optical film, wherein the packaging layer is disposed on a surface of the panel, the plurality of light-emitting elements are arranged in the packaging layer, and the optical film covers the packaging layer;
forming an open zone in the optical film by irradiating a part of the optical film with a laser beam, wherein the open zone corresponds to a bubble, and the bubble exists between the optical film and the packaging layer;
removing the bubble by performing a pressurization and heating procedure on the display device; and
filling at least one adhesive in the open zone.
